(19) United States
(12) Patent Application Publication
(10) Pub. No.: US 2003/0126742 A1
(43) Pub. Date: Jul. 10, 2003

(54) Method of fabrication of ZnO nanowires

(76) Inventors: Jyh-Ming Ting, Tainan City (CN); Yee-Shin Chang, Tainan City (CN)

Correspondence Address: WILDMAN, HARROLD, ALLEN & DIXON, 225 WEST WACKER DRIVE, CHICAGO, IL, 60606, US

(21) Appl. No.: 10/279,631

(22) Filed: Oct. 24, 2002

(30) Foreign Application Priority Data
Dec. 25, 2001 (CN) 90132235

(51) Int. Cl. H01L 21/302; H01L 21/461

(52) U.S. Cl. 29/874; 29/830; 29/831; 438/754

(57) ABSTRACT

The present invention relates to a method of fabrication of ZnO nanowires, which uses the sputter deposition technique to form the ZnO nanowires on non-single-crystal the copper metallized substrate.

### BACKGROUND OF THE INVENTION

(A) Field of the Invention

The present invention relates to a method of fabrication of ZnO nanowires, which uses the sputter deposition technique to form the ZnO nanowires on the copper metallized substrate.

(B) Description of Related Art

ZnO is a hexagonal close-packed structure, that is a wurtzite type structure, which provides excellent dielectric and optical characteristics, so as to be widely applied to various photoelectric and semiconductor fields. Following the progress of the nano-technique, the material science is advanced to the field of nanometers providing even smaller devices and components, wherein the fabrication for nanowires is one of the important techniques. The ZnO has a very unique electric, magnetic and optical characteristics and application potentials, which can be applied as the electric components, photoelectric components for the semiconductor.

From 1960, the vapor-liquid-solid (VLS) reaction method was used to fabricate the silicon whiskers. Except the silicon whiskers, the researches for ZnO nanowires are more emphasized, and there are few publications disclosing the relative techniques, such as heating the Zn powder in 99.99% purity and containing nanoparticles up to 900° C. for forming ZnO nanowires with the diameter range between 30 nm to 60 nm [Journal of Crystal Growth, 234(1):171-175 January 2002]; moreover, the technique for using physical vapor deposition method to fabricate the ZnO nanowires are also disclosed [Applied Physics Letters, 78(4):407-409 Jan. 22, 2001]; and, the growing mechanism for the nanowires in these two methods is controlled by the conventional VLS method. Nevertheless, using VLS method to form the nanowires has the following disadvantages: (1) residual metal catalyst, and (2) lower productivity. Further, the method using the conventional technique to form the nanowires is much limited, because the deposited substrate material has to be a single-crystal structure (e.g. sapphire and diamond). Thus, developing an innovative and simple technology to fabricate ZnO nanowires becomes a big challenge in the nanometer field.

### SUMMARY OF THE INVENTIION

With respect to the limitation of the prior art, the object of the present invention is to provide an innovative method of fabrication of ZnO nanowires, which uses sputter method to form ZnO nanowires on the copper metallized substrate.

The fabrication method according to the present invention employs the physical method to fabricate the ZnO nanowires, wherein the selection for the substrate is not limited to the single-crystal structure, thus the disadvantages in the prior art can be overcome. The fabrication method comprises: providing a substrate; conducting copper metallization on the surface of the substrate; depositing ZnO on the surface of the copper metallized substrate; and, forming ZnO nanowires.

The above-mentioned substrate may be the material of single-crystal or non-single-crystal, such as silicon, metal or other compounds, preferably the silicon.

The above-mentioned copper metallization method is not particularly limited, and may be conducted in a physical or chemical manner, such as the plating technology or the ion beam sputter (IBS) deposition technology.

The above-mentioned deposition method for ZnO nanowires is a physical method, such as RF sputter deposition method.

The above-mentioned deposition method can be used to form ZnO thin film and/or ZnO nanowires.

The above-mentioned ZnO nanowires are formed on the ZnO thin film, or on the copper metallized substrate directly, and the orientation of the ZnO nanowires may be controlled.

The above-mentioned ZnO thin film is in polycrystalline structure, and the ZnO nanowires is of single-crystal structure.

The above-mentioned ZnO nanowires all have the similar diameters.

### BRIEF DESCRIPTION OF DRAWINGS

FIG. 1 is the flow chart for the fabrication method according to the present invention.

FIG. 2 is the scanning electron microscopy (SEM) micrographs for the ZnO thin film formed by the fabrication method according to the present invention.

FIG. 3 is the SEM micrographs for the ZnO nanowires formed by the fabrication method according to the present invention.

FIG. 4 is a SAD diagram illustrating the ZnO nanowires as single-crystal structure.

### DETAILED DESCRIPTION OF THE INVENTION

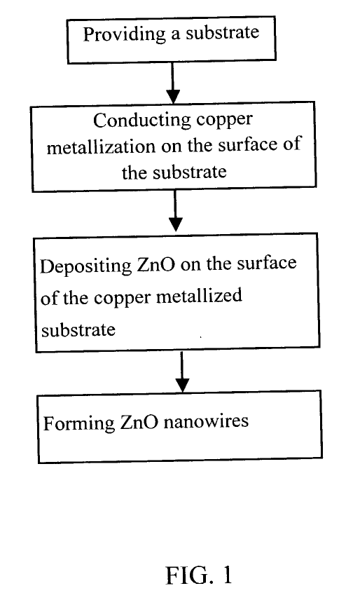

As shown in FIG. 1, the present invention provides a method of fabrication of ZnO nanowires, which comprises: providing a substrate; conducting copper metallization on the surface of the substrate; depositing ZnO on the surface of the copper metallized substrate; and, forming ZnO nanowires.

The above-mentioned substrate may be the material of single-crystal or non-single-crystal, such as silicon, metal or other compounds, preferably the silicon.

The above-mentioned copper metallization method is not particularly limited, and may be conducted in a physical or chemical manner, such as the plating technology or the ion beam sputter (IBS) deposition technology.

The above-mentioned deposition method for ZnO nanowires is a physical method, such as RF sputter deposition method.

The above-mentioned deposition method can be used to form ZnO thin film and/or ZnO nanowires.

The above-mentioned ZnO nanowires are formed on the ZnO thin film, or on the copper metallized substrate directly, and the orientation of the ZnO nanowires may be controlled.

The fabrication method according to the present invention is described in details through the following embodiments:

Embodiments

1. Substrate Preparation

A suitable substrate material is selected, such as Si wafers, which provides a Ti metal layer as the starting material for copper metallization. The metallization is performed using a commercial plating technique or an ion beam sputter (IBS) deposition method. In the IBS deposition method, copper was deposited using an ion beam energy of 30 mA×750 V, a pressure of 5.3×10⁻² Pa (4×10⁻⁴ torr), and a deposition time of 30 minutes in an Ar environment.

2. Deposition of ZnO Thin Films

The present invention uses the sputter deposition method, such as a radio frequency magnetron sputter deposition technique, for depositing the ZnO on the copper metallized substrate, which is under a pressure lower than 6.7×10⁻⁴ Pa (5 mtorr), and an RF power of 200W, a working distance of 45 mm, and uses various mixture ratios of O₂/Ar(0.1, 0.2, 0.3 and 0.4) to deposit ZnO for about 30 minutes.

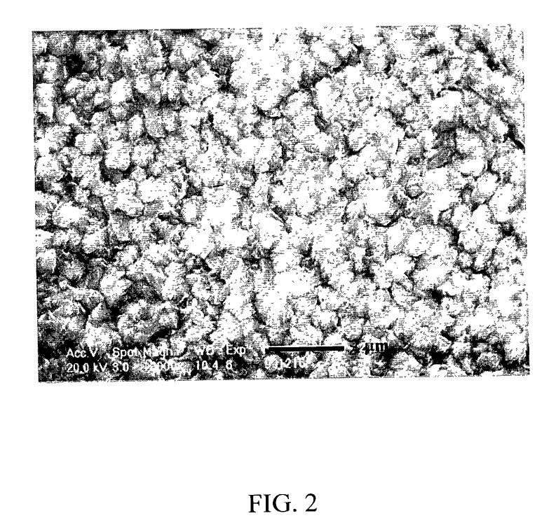

FIG. 2 shows a micrograph of ZnO thin film formed by the method according to the present invention. After the thin film is analyzed by the instrument, the ZnO thin film shows to be a polycrystalline structure, and has the purity in 99.999% and the diameter in about 2 inches.

3. Fabrication of ZnO Nanowires

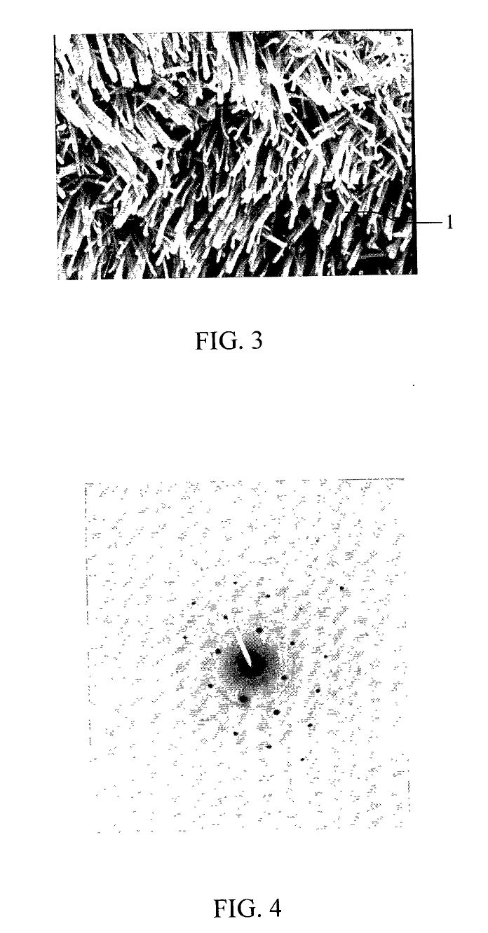

The above-mentioned steps according to the present invention can be used to form ZnO nanowires 1, as shown in FIG. 3, and the orientation of the ZnO nanowires 1 appears to be random, and have similar diameters (average diameters about 30 nm) along the axial direction of the nanowires 1. The nanowires 1 are examined by the selected area diffraction (SAD) technology, and the result shows that the ZnO nanowires 1 fabricated according to the present invention is a single-crystal structure, as shown in FIG. 4. The ZnO nanowires 1 can be formed on the ZnO thin film, or on the copper metallized substrate directly.

In a summary, the method of fabrication of ZnO nanowires according to the present invention can select various substrates, for example the non-single-crystal or single-crystal material as the substrate, and uses the sputter deposition technique to fabricate the ZnO nanowires in single-crystal structure.

A preferred embodiment of the invention was described above. It should be noted that the present invention is not limited by the embodiment, and can be made with various modification by those skilled in the art without departing from the spirit and scope of the present invention. Thus, the protection scopes for the present invention are defined in the appended claims.

The present invention provides a method of fabrication of ZnO nanowires, which can select the single-crystal or non-single-crystal structure material as the substrate, and uses a normal sputter deposition technique for forming ZnO nanowires. In comparison with the prior art, the conventional processing method for the ZnO nanowires must use a substrate in single-crystal structure, and operate with a chemical deposition method to meet various limitations. The fabrication method according to the present invention makes a great breakthrough and advance, so that the research for nano-technology may have greater development potentials, such as in the future photoelectric and semiconductor industries.

What is claimed is:

1. A method of fabrication of ZnO nanowires, which comprises:
providing a substrate;
conducting copper metallization on the surface of the substrate;
depositing ZnO on the surface of the copper metallized substrate; and
forming ZnO nanowires.

2. The method of fabrication of ZnO nanowires of claim 1, wherein said substrate can be single-crystal or non-single-crystal material.

3. The method of fabrication of ZnO nanowires of claim 1, wherein said substrate can be silicon, metal or metal compound.

4. The method of fabrication of ZnO nanowires of claim 1, wherein said copper metallization method can be a physical or chemical method.

5. The method of fabrication of ZnO nanowires of claim 1 or 4, wherein said copper metallization method can be a plating technology or an ion beam sputter (IBS) deposition technology.

6. The method of fabrication of ZnO nanowires of claim 1, wherein said deposition method for ZnO is a physical method.

7. The method of fabrication of ZnO nanowires of claim 6, wherein said physical method is a sputter deposition method.

8. The method of fabrication of ZnO nanowires of claim 1, wherein said deposition method can be used to form ZnO thin film and/or ZnO nanowires.

9. The method of fabrication of ZnO nanowires of claim 1, wherein said ZnO nanowires is formed on ZnO thin film, or on the copper metallized substrate directly.

10. The method of fabrication of ZnO nanowires of claim 8 or 9, wherein said ZnO thin film is a polycrystalline structure.

11. The method of fabrication of ZnO nanowires of claim 1, wherein said ZnO nanowires is a single-crystal structure.

12. The method of fabrication of ZnO nanowires of claim 1, wherein said substrate can have the Ti metal layer as the starting material for copper metallization.

13. A method of fabrication of ZnO nanowires, which comprises:
providing a non-single-crystal substrate;
conducting copper metallization on the surface of the substrate;
depositing ZnO on the surface of the copper metallized substrate by sputter deposition method; and
forming ZnO nanowires.

14. The method of fabrication of ZnO nanowires of claim 13, wherein said substrate is a Si wafer.

15. The method of fabrication of ZnO nanowires of claim 13, wherein said copper metallization method can be a plating technology or an ion beam sputter (IBS) deposition technology.

16. The method of fabrication of ZnO nanowires of claim 13, wherein said sputter method can be used to form ZnO thin film and/or ZnO nanowires.

17. The method of fabrication of ZnO nanowires of claim 13, wherein said ZnO nanowires is formed on ZnO thin film, or on the copper metallized substrate directly.

18. The method of fabrication of ZnO nanowires of claim 16, wherein said ZnO thin film is a polycrystalline structure.

19. The method of fabrication of ZnO nanowires of claim 17, wherein said ZnO thin film is a polycrystalline structure.

20. The method of fabrication of ZnO nanowires of claim 13, wherein said ZnO nanowires is a single-crystal structure.
